(19) United States
(12) Patent Application Publication
(10) Pub. No.: US 2026/0271421 A1
(43) Pub. Date: Sep. 10, 2026

(54) OPTOCOUPLER

(71) Applicant: Fraunhofer-Gesellschaft zur Förderung der angewandten Forschung e.V., München (DE)

(72) Inventors: René KIRRBACH, Dresden (DE); Tobias SCHNEIDER, Dresden (DE); Kai SCHMIEDER, Dresden (DE)

(73) Assignee: Fraunhofer-Gesellschaft zur Förderung der angewandten Forschung e.V., München (DE)

(21) Appl. No.: 19/558,507

(22) Filed: Mar. 6, 2026

(30) Foreign Application Priority Data
Mar. 6, 2025 (DE) 102025108617.6

(51) Int. Cl. H10F 55/20; H05K 1/181; H10H 29/20

(52) U.S. Cl. CPC H10F 55/20; H10H 29/20; H05K 1/181

(57) ABSTRACT

An optocoupler includes a first optical device having beamforming optics, wherein the optical device is configured to emit an optical-fiberless signal, and a second optical device galvanically isolated from the first optical device and configured to receive the optical-fiberless signal and convert it into an electrical signal. A holding structure is configured to position the first optical device and the second optical device in a fixed relative position with respect to one another for the transmission and reception of the optical-fiberless signal.

### CROSS-REFERENCE TO RELATED APPLICATION

This application claims priority from German Patent Application No. DE 10 2025 108 617.6, which was filed on Mar. 6, 2025, and is incorporated herein in its entirety by reference.

The present invention relates to an optocoupler and to a system with such an optocoupler. In particular, the present invention relates to a high-speed optocoupler, including those with a high insulation voltage.

### BACKGROUND OF THE INVENTION

Circuits with a high bandwidth nowadays use advanced transistor technologies. These transistors are very small, enabling very fast switching processes. On the other hand, their dielectric strength is severely limited. If measurements are to be made at high voltages, such as >1 kV, e.g., potential isolation by galvanic isolation is mandatory. Optocouplers are used to be able to transmit data across a comparatively large potential difference. In this case, new applications place ever more demanding demands on size, data rate and insulation voltage, which current optocouplers cannot or scarcely can meet.

For conventional optocouplers, the data rate is typically limited to 50 Mbps, since LEDs are usually used within the optocouplers. The insulation voltage within the optocoupler is determined by its size (distance between transmitter and receiver) and the material in between. However, a breakdown is also possible on the printed circuit board surface and/or optocoupler housing surface and is indeed much more probable.

The known technical situation results in optocouplers with high insulation voltages of more than 1 kV being large and expensive. It becomes even clearer if higher data rates are required. A plurality of optocouplers then have to be used in parallel, which entails high space requirements and high costs.

One alternative is the use of optical fiber-coupled transceivers, wherein one transceiver each is placed at each end and the insulation path is bridged by an optical fiber. This approach has essentially two disadvantages: the structure is large since entire transceiver modules are required, and is at the same time cost-intensive.

Accordingly, a possibility of enabling reliable data transmission at high data rates even at high insulation voltages would be desirable.

This, it is an object of the present invention to provide an optocoupler that enables information to be transmitted reliably and at high data rates even at high insulation voltages.

### SUMMARY

An embodiment may have an optocoupler comprising: a first optical device having beamforming optics configured to emit an optical-fiberless signal using the beamforming optics; a second optical device galvanically isolated from the first optical device and configured to receive the optical-fiberless signal and convert it into an electrical signal; a holding structure configured to position the first optical device and the second optical device in a fixed relative position with respect to one another for the transmission and reception of the optical-fiberless signal.

Another embodiment may have a system comprising: an optocoupler according the invention; and a data source coupled to the first optical device in order to transmit data to the second optical device by means of the optical-fiberless signal; and a data receiver configured to receive the data from the second optical device.

A core idea of the present invention is to have recognized that the use of optionally unidirectionally operated optical transceivers for transmitting optical-fiberless signals offers the possibility of overcoming the above-mentioned disadvantages and reliably transmitting high data rates even at high insulation voltages of several kilovolts or several tens of kilovolts or even more.

According to an embodiment, an optocoupler that comprises a first optical device having beamforming optics configured to emit an optical-fiberless signal is provided. Furthermore, a second optical device that is galvanically isolated (or separated) from the first optical device and that is configured to receive the optical-fiberless signal and convert it into an electrical signal is arranged. A holding structure is configured to position the first optical device and the second optical device in a fixed relative position with respect to one another for the transmission and reception of the optical-fiberless signal.

According to an embodiment, an optical transmission path between the first optical device and the second optical device comprises a length of at least 5 mm. Thus, insulation strengths of more than 1 kV can already be obtained and such distances can be transmitted without problems using optical-fiberless signals. The length of the transmission path can also be less than 5 mm or significantly more than 5 mm, e.g. several tens of millimeters.

According to an embodiment, the optical-fiberless signal is a first optical-fiberless signal, wherein the second optical device is configured to transmit a second optical-fiberless signal to the first optical device. Thus, a bidirectional communication for mutual data exchange can be enabled. In this case, it is possible that the communication is set up for the half-duplex as well as for the full-duplex mode.

According to an embodiment, the optocoupler includes an electrical insulation region between the first optical device and the second optical device, e.g. as an insulation element or a recess, which can further increase the breakdown voltage. The insulation element is typically characterized by a high dielectric strength.

According to an embodiment, the holding structure includes a circuit board structure and the first optical device and the second optical device are arranged on the circuit board structure. This enables a precise relative positioning of the devices with respect to one another and also the interconnection with further elements.

According to an embodiment, the first optical device is arranged on an optics mounting side of a first circuit board element of the circuit board structure and the second optical device is arranged on an optics mounting side of a spaced apart second circuit board element, wherein the optics mounting sides face or face away from one another. This enables a further degree of freedom in the implementation of data transmission systems. In other implementation, the optics mounting sides face in the same direction, e.g., which may be obtained by dividing the circuit board structure into a plurality of sub-elements.

According to an embodiment, an optocoupler includes a first electrical insulation element that is arranged on the first circuit board element and faces the second circuit board element, and, furthermore, a second electrical insulation element that is arranged on the second circuit board element and faces the first circuit board element is provided. This enables manufacturing of the individual elements, e.g. of a respective circuit board element with an optical device arranged thereon and an insulation element facing a later communication partner, to the effect that the individual communication partners may be manufactured and/or arranged individually.

According to an embodiment, the optocoupler is formed such that the first electrical insulation element at least partially encapsulates the first optical device and/or the second electrical insulation element at least partially encapsulates the second optical device. As a result, additional protection of the optical devices from electrical voltage on the one hand, but also from further environmental influences, such as moisture or contamination, may be obtained.

According to an embodiment, the circuit board structure includes a recess along a distance between the first optical device and the second optical device, e.g. a depression or a free space or continuous recess between the optics mounting sides of the circuit board structure. An expansion perpendicular to the distance between the two optical devices provides a leakage current path extension, since, on account of the recess, leakage currents have to cover detours around the recess, further increasing the dielectric strength of the optocoupler.

According to an embodiment, the holding structure includes an electrically insulating insulation element that is at least partially arranged along a distance between the first optical device and the second optical device. With regard to electrical leakage currents the insulation element may provide a similar effect like a recess, wherein the materials used for the insulation element may provide a comparatively higher dielectric strength.

According to an embodiment, the insulation element is formed to be transparent for a wavelength range of the optical-fiberless signal and is arranged in a course of a path of the optical-fiberless signal. This enables a particularly advantageous insulation of the two optical devices from one another and also enables, in one configuration, at least one of the two optical devices to be at least partially encapsulated with the insulation element, e.g. by the device being cast in or being covered as a type of housing.

According to an embodiment, the insulation element is pressed into a recess of the holding structure in a contact region and comprises, in the contact region, elevations or depressions, also referred to as lugs, with respect to the holding structure, configured to provide a clamping force with respect to the holding structure. This enables particularly advantageous manufacturing with high protective effect of the insulation element at the same time.

According to an embodiment, an optocoupler includes a leakage current path extension configured to extend a path length of a leakage current compared to a direct path and between the first optical device and the second optical device, increasing the dielectric strength.

According to an embodiment, the first optical device and the second optical device form a first transmitter pair. Overall, the optocoupler includes a plurality of transmitter pairs configured for temporally and/or spatially parallel operation and arranged on the holding structure. This enables the bandwidth of the optocoupler to be increased compared to a single transmitter pair, while the disadvantages of fiber-bound transmitters may be avoided.

According to an embodiment, the optocoupler is configured to transmit, on the basis of mutually different sensor elements, sensor data for mutually different sensor channels having mutually different transmitter pairs. This enables high flexibility in the implementation of the optocoupler. It is also conceivable that the different data channels are also other signals, e.g. control signals, or that some channels contain control signals and other sensor signals.

According to an embodiment, the optocoupler is configured for operation in an optics arrangement, wherein the optics arrangement extends parallel to an optics plane and wherein the first optical device and the second optical device are arranged in a corresponding plane parallel to the optics plane. For example, the optical devices are configured to exchange the optical-fiberless signal tangentially to a printed circuit board or the like and are located substantially in the same plane with respect to the printed circuit board plane. According to an alternative embodiment, the first optical device and the second optical device are arranged opposite one another in different planes, which may enable simpler optics for forming the optical-fiberless signal and, alternatively or additionally, may also enable a smaller space requirement on a printed circuit board plane.

According to an embodiment, an optical transmitter of the first optical device and an optical receiver of the second optical device are positioned in a radial arrangement, providing additional degrees of freedom. In such an implementation, the optical transmitter may enclose the optical receiver at the output aperture; or the optical receiver may enclose the optical transmitter at the output aperture.

According to an embodiment, the optocoupler is formed as an integrated device or part of an integrated system, enabling a compact design.

According to an embodiment, the first optical device is configured to emit the optical-fiberless signal substantially in parallel to a mounting surface on which the first optical device is arranged; or wherein the first optical device is configured to emit the optical-fiberless signal substantially perpendicular to the mounting surface, for instance with respect to an arrangement next to one another or above one another.

According to an embodiment, a system includes an optocoupler described herein and a data source that is coupled to the first optical device in order to transmit data to the second optical device by means of the optical-fiberless signal. A data receiver is configured to receive the data from the second optical device.

According to an embodiment, the data source includes one or more sensors, a field-programmable gate array, FPGA, and/or a function-specific integrated circuit, ASIC. This advantageously enables small optocouplers or small systems.

According to an embodiment, the data source is electrically coupled to a low-potential side of the system and the data receiver is electrically coupled to a high-potential side of the system. An inverse implementation is readily possible, according to which the data source is electrically coupled to the high-potential side of the system and the data receiver is electrically coupled to the low-potential side of the system. Due to the optocoupler used, data transmission may take place reliably between the two potential sides. The term “potential” in this case relates to the electrical potential (Coulomb potential).

According to an embodiment, the system is formed as an integrated system, enabling a space-saving implementation.

### BRIEF DESCRIPTION OF THE DRAWINGS

Embodiments of the present invention will be detailed subsequently referring to the appended drawings, in which:

FIG. 1 shows a schematic block circuit diagram of an optocoupler according to an embodiment;

FIG. 2 shows a schematic perspective view of a system according to an embodiment that comprises an optocoupler according to an embodiment;

FIG. 3 shows a schematic perspective view of a system according to an embodiment in which the optocoupler comprises a recess of the holding structure;

FIG. 4 shows a schematic perspective view of a system according to an embodiment with an insulation element between the optical devices of the optocoupler;

FIG. 5 shows a schematic perspective view of a system according to an embodiment in which an optocoupler includes a plurality of transmitter pairs for optical-fiberless signals;

FIG. 6 shows a schematic block circuit diagram of an optocoupler according to an embodiment that is configured for a bidirectional communication;

FIG. 7 shows a schematic perspective view of a system according to an embodiment, wherein the optical devices of the optocoupler are arranged on different circuit board elements;

FIG. 8 shows a schematic block circuit diagram of a system according to an embodiment, wherein the transceivers of the optocoupler are present in a stacked arrangement;

FIG. 9 shows a schematic plan view of a system according to an embodiment;

FIG. 10 shows a schematic top view of a system similar to FIG. 9, wherein the holding structure is configured with two separate circuit boards and a respective insulator; and

FIG. 11 shows a schematic top view of a system according to an embodiment, wherein at least one transceiver is encapsulated by an insulation element.

### DETAILED DESCRIPTION OF THE INVENTION

Before embodiments of the present invention are explained in more detail below with reference to the drawings, it is pointed out that identical, functionally identical or identically acting elements, objects and/or structures are provided with the same reference signs in the different figures, so that the description of these elements illustrated in different embodiments is interchangeable or can be applied to one another.

Embodiments described below are described in connection with a multitude of details. However, embodiments can also be implemented without these detailed features. Furthermore, for the sake of comprehensibility, embodiments are described using block circuit diagrams as a replacement for a detailed illustration. Furthermore, details and/or features of individual embodiments can be readily combined with one another, as long as it is not explicitly described to the contrary.

The following embodiments relate to an optical-wireless signal transmission or data transmission synonymously referred to as optical-wireless and optical-fiberless. In the context of the embodiments described herein, this can also be referred to as LiFi or Li-Fi (Light Fidelity). Terms such as IrDA (Infrared Data Association) or OWC (Optical Wireless Communication) can be understood, inter alia, as optical-wireless transmissions. This means that the terms “optical-wireless data transmission”, “optical-fiberless transmission” and “LiFi” are used synonymously. In this case, optical-fiberless data transmission is understood to mean transmitting an electromagnetic signal through a free transmission medium, for example air or another gas or a fluid. For this purpose, e.g., wavelengths in an ultraviolet (UV) range with at least 100 nm, and the infrared range, for example at most 1550 nm, may be used, although other wavelengths that differ from wavelengths used for radio standards are also possible. An optical-wireless data transmission is also to be distinguished from a fiber-optical data transmission, e.g., which is implemented using optical wave guides or optical wave guide cables (or optical fibers or fiber optic cables). The terms transmitter and sender are used as synonyms. The same applies to the terms receiver and recipient.

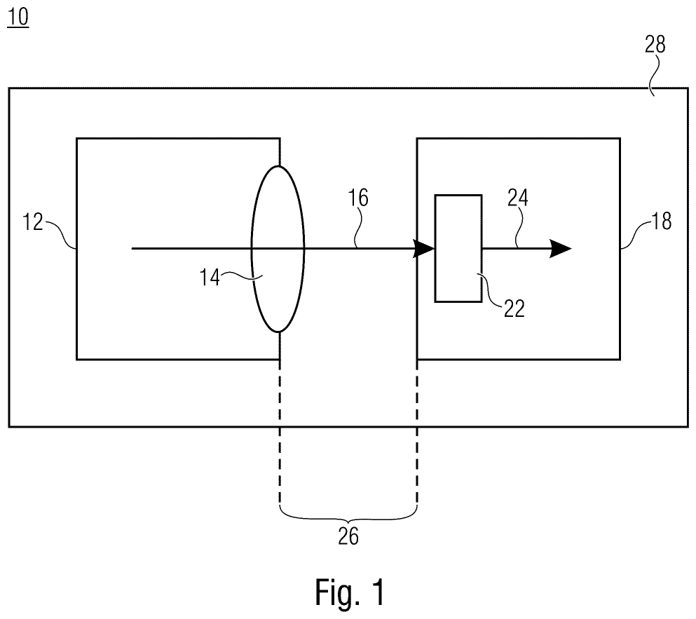

FIG. 1 shows a schematic block circuit diagram of an optocoupler 10 according to an embodiment. The optocoupler 10 includes a first optical device 12 having beamforming optics 14 and is configured to emit an optical-fiberless signal 16. Among other things, the optical-fiberless signal 16 differs from simple LED or laser diode transmitters based on the beamforming by the optics 14. Furthermore, a signal modulation and an amplifier circuit can also be arranged to drive an element for emitting or generating the optical-fiberless signal 16. In an optional bidirectional configuration of the optocoupler for a bidirectional implementation, both the first optical device 12 and the communication partner, a second optical device, may be configured as an optical transceiver, e.g. to transmit optical-fiberless signals in a free medium.

In such a case, the second optical device 18 may also comprise beamforming optics, wherein this is optionally also possible for the receiving case. The second optical device 18 includes a receiver device 22 configured to provide an electrical signal 24 based on the optical-fiberless signal 16, e.g. at an output interface or for a component of the optocoupler. For example, the receiver device 22 may include a photodetector, e.g. a photodiode or the like.

According to an optional embodiment, an optical transmission path between the optical devices 12 and 18 may comprise a length 26 of at least 5 mm, at least 10 mm, at least 20 mm or more. Thus, and based on a material arranged in the transmission path or other properties, an insulation strength or breakdown voltage of the optocoupler may be at least partially adjusted.

The optocoupler includes a holding structure 28 configured to position the first optical device 12 and the second optical device 18 in a fixed relative position with respect to one another for the transmission and reception of the optical-fiberless signal 16. The fixed relative position may be obtained, e.g., by screwing or soldering or the like, and cause a relative position that is possibly invariable during operation. This does not exclude the implementation of possibilities for adjustment or calibration, according to which changes in the relative position are possible, e.g., for adjusting the operating state.

The holding structure 28 may include, e.g., a substrate or a frame that is not necessarily plate-shaped, wherein, e.g., with regard to the supply of electrical energy to the components, wiring carriers with a polymeric insulating material—such as printed circuit board substrates—as well as inorganic carriers—e.g., ceramic-based—may be suitable.

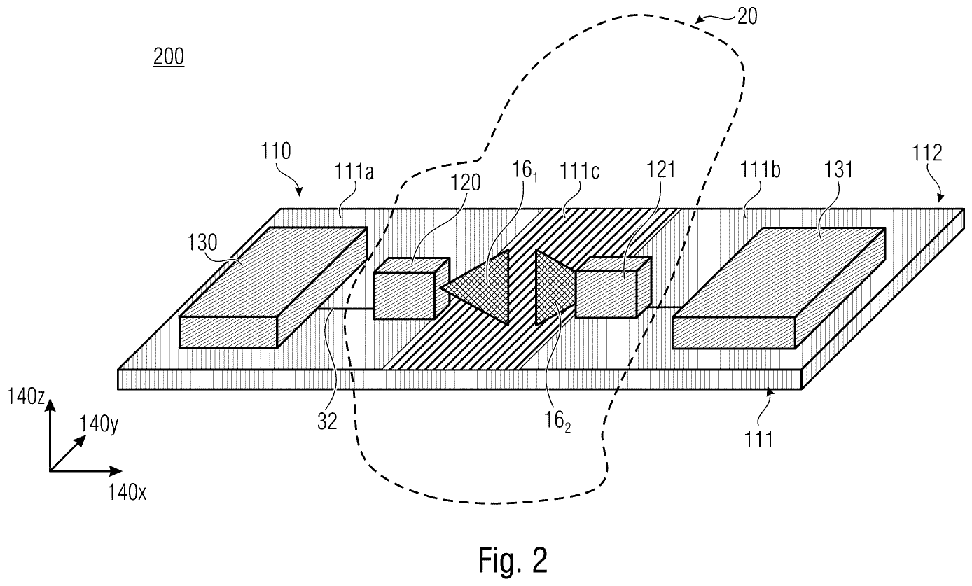

FIG. 2 shows a schematic perspective view of an optocoupler 20 according to an embodiment, comprising a plurality of extensions with respect to the optocoupler 10, each of which is optional but can be easily combined with one another.

Thus, the optocoupler 20 may be configured, e.g., for a bidirectional information exchange, and a first optical device 120 used for this purpose, which may correspond to the optical device 12 and/or 18, may be configured to transmit an optical-fiberless signal 161 to a second optical device 121, which may correspond to the optical device 12 and/or 18. The optical device 121 may in turn be configured to transmit an optical-fiberless signal 162 to the first optical device 120. When using corresponding methods for multiple access or other concepts for signal separation, the transmission of the signals 161 and 162 may also take place simultaneously or at the same time, e.g., using different wavelengths. Alternatively or additionally, a half-duplex method may also be used. As methods for multiple access, e.g., a time-division multiplex, a wavelength-division multiplex, a spatial multiplex generated or provided, e.g., by the lens of the transceiver, and further multiplexing methods, and in particular also combinations thereof, may be used.

The optocoupler 20 is illustrated as part of a system 200 that furthermore comprises a data source 130 and a data receiver 131. It is pointed out that, in particular in view of the bidirectional communication of the optocoupler 20, the functions of the data source 130 and of the data receiver 131 can also be easily interchanged and/or mutually supplemented, so that at least one of the two blocks 130 and 131 can be used as data source and data receiver. It is also possible that the blocks 130 and 131 act both as data source and data receiver at the same time. For example, the block 130 can generate sensor data and forward it as a data source and at the same time also receive control data from 131, which also makes it a data receiver.

Transmission of information between the data source 130 and the first optical device 120, which may correspond, e.g., to the first optical device 12, may take place, e.g., as an electrical and/or optical or other type of signal 32. The same applies to the transmission between a second optical device 121 formed, e.g., as optical device 12 and the data receiver 131. If, e.g., the data receiver 131 is formed or arranged as part of the optocoupler, conversion of the optical-fiberless signal 161 into an electrical signal may also take place only in the region of the data receiver 131.

A holding structure 111, which may correspond to the holding structure 28, is configured, e.g., as a circuit board and possibly, but not necessarily, comprises three regions 111a, 111b and 111c, wherein the regions 111a and 111b are assigned, e.g., to different potential regions, such as a region 110 with a low electrical potential and 112, a region with a comparatively higher electrical potential, wherein the potentials of the regions 110 and 112 may be readily separated by a plurality of kV, a plurality of 10 kV or more. The term potential in this case relates to the electrical potential (Coulomb potential).

A region 111c may be used as an insulation region that may supply such insulation voltages based on a distance between the optical devices 120 and 121 and possibly based on further components or features.

The system 200 may comprise one or more sensors, or may be coupled thereto, that may, e.g., be part of the data source 130 or may be coupled thereto. Alternatively or additionally, the data source 130 and/or the data receiver 131 may include a field-programmable gate array (FPGA) and/or a function-specific integrated circuit (ASIC).

The system 200 may also be readily formed as an integrated system, enabling a small design.

The insulation region 111c may at least partially supply the electrical dielectric strength of the optocoupler 20 as an electrical insulation region between the optical devices 120 and 121. The insulation region 111c may supply one or more different mechanisms for supplying the dielectric strength. Thus, e.g., the physical distance is a first means for supplying the dielectric strength, whose increase also increases the dielectric strength. A surface roughness, e.g. due to grooves or the like, in particular extending perpendicular to a direction between the optical devices 120 and 121, may already increase the path length that a leakage current has to cover and thereby increase the dielectric strength. In an embodiment of the present invention, a groove structure is therefore provided in the insulation region 111c to extend a path length for the leakage current compared to a direct path between the optical devices 120 and 121.

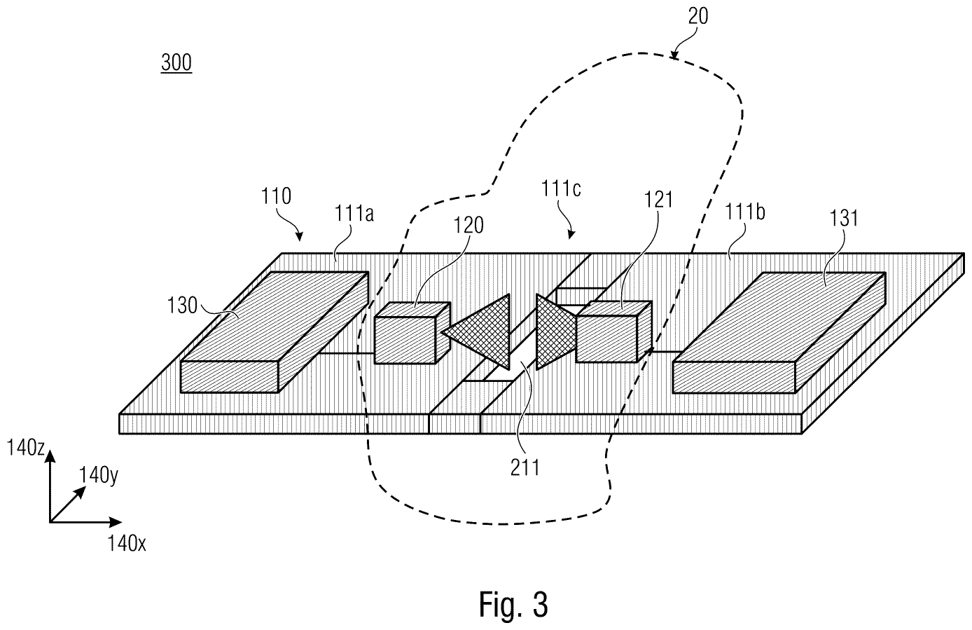

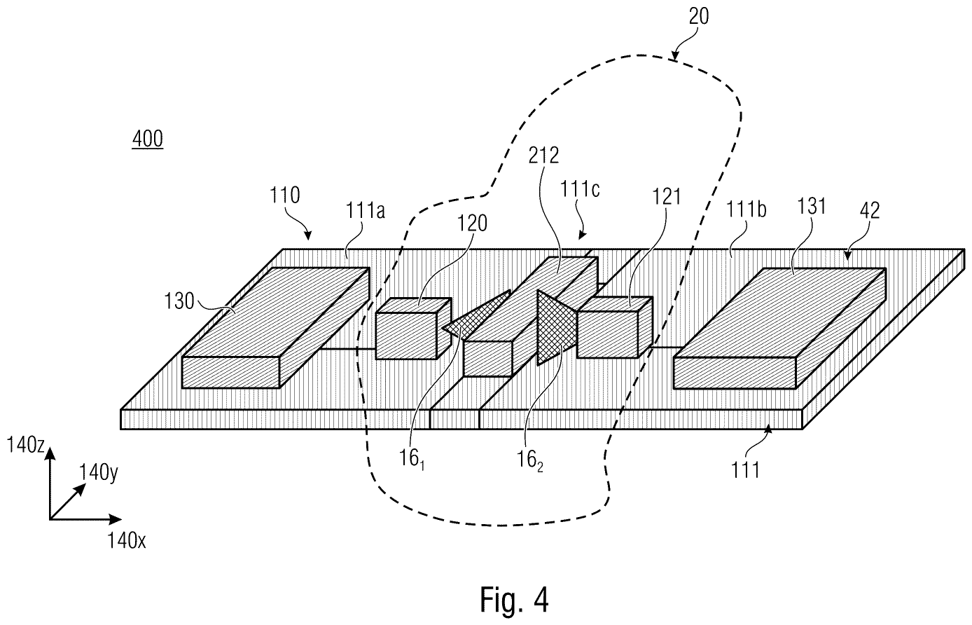

Further advantageous embodiments may be advantageously implemented when using a circuit board as a holding structure, but are not dependent thereon. Thus, a recess described in connection with FIG. 3, e.g. a depression or a hole, may be provided in the insulation region 111c and/or an insulation element may be provided, e.g., as described with reference to FIG. 4.

FIG. 2 illustrates that an implementation of the holding structure as a circuit board structure enables further components, e.g., the data source 130 and/or the data receiver 131, to be arranged and coupled to the optical devices 120/121. It is possible but not necessary for the holding structure to be formed in one piece. As disclosed in connection with embodiments of the present invention, the holding structure, e.g. a circuit board structure, may also be formed from a plurality of individual elements that are possibly positioned relative to one another and/or rotated relative to one another.

FIG. 2 shows an implementation of the present invention as a novel optocoupler that consists of or includes at least two optical-wireless devices, preferably transceivers, which in some embodiments communicate substantially tangentially, as illustrated by the direction 140x, to the substrate surface, e.g. of a circuit board. Preferably, no optical fibers are used, i.e., the transmission between the two optical devices is at least partially free of an optical fiber. The two transceivers 120, 121 may be placed on a circuit board or on two different circuit boards or substrates. The distance between the transceivers may at least partially determine the insulation voltage.

The insulation region 111c on the circuit board 111 is preferably free of metallic conductors. Since the range of the transceivers is in the range of several centimeters and more, high insulation voltages of several kV, several 10 kV or more may be realized. In this way, the circuit board of FIG. 2 may be separated into a region 110 with lower electrical potential and a region 112 with higher electrical potential, wherein this description is mutually exchangeable. The transceivers may use LEDs or laser diodes so that they may achieve data rates of several Gbps. This means that signal generating means of an optical device described herein may include such an LED or laser diode configured to provide the optical-fiberless signal. The transceivers may unidirectionally or bidirectionally transmit data in the half-duplex mode or full-duplex mode from the block 130 in the low-potential range to the block 131 in the high-potential range and/or vice versa. A duplex mode is not necessary in a unidirectional operation.

In other words, FIG. 2 shows an embodiment with an optocoupler including two transceivers 120, 121 on a printed circuit board 111, wherein the transceivers communicate tangentially to the printed circuit board surface, e.g. along the direction 140x.

Optocouplers and/or systems described herein may be provided as integrated devices and/or systems, enabling simple handling and good manufacturability.

FIG. 3 shows a schematic block circuit diagram of a system 300 according to an embodiment that implements one or more of the advantageous embodiments of FIG. 2, but comprises a modification of the holding structure 111 or the circuit board structure with respect to the system 200, to the effect that a recess is implemented along a distance between the optical devices 120 and 121. The distance between the optical devices 120 and 121 extends e.g. along the direction 140x and the recess 211 includes an expansion perpendicular thereto, along the distance 140y, which at least partially provides a leakage current path extension. This means that a path for leakage currents is extended between the optical devices 120 and 121 based on the recess or slot 211. Such a recess 211 may be inserted into the holding structure, e.g. a circuit board, in a simple manner.

In other words, in order to reduce the influence of leakage currents on the circuit board and in particular in the case of moisture, it is possible to provide a recess within the substrate or the circuit board in the insulation region 111c. The shape or geometry of such an interruption may be arbitrary. In FIG. 3, this is exemplarily illustrated as a simple slot 211, wherein the slot 211 does not have to be configured on the full length or width of the circuit board along the direction 140y, e.g. in order to still ensure a mechanical stability or relative fastening on the sides. If necessary, this may also be obtained by additional mechanical means in order to be able to sever the recess 211 over the entire expansion along the direction 140y, i.e. the width perpendicular to the communication direction 140x.

In other words, FIG. 3 shows an embodiment in which the insulation voltage is increased by avoiding leakage currents in the region of the recess. In the embodiment of FIG. 3, this may be achieved by a simple slot in the circuit board.

A further preferred embodiment is illustrated with reference to FIG. 4. FIG. 4 shows a schematic block circuit diagram of a system 400 according to an embodiment that also includes the optocoupler 20, wherein, alternatively or in addition to the recess 211 of FIG. 3, an electrically insulating element 212 for preventing leakage currents is arranged along the distance between the optical devices 120 and 121. The dielectric strength of the optocoupler 20 and/or of the system 400 may be increased by this barrier. Advantageous materials for this are e.g. quartz materials, glass, silicate materials or plastics. The insulation element may comprise an increased dielectric strength, compared to air, of more than 100 V, more than 1 kV, more than 5 kV or more than 10 kV, for example.

In the implementation of FIG. 4, the insulation element 212 is arranged in the course of the path of the optical-fiberless signals 161 and 162, i.e. the optical-fiberless signals run through the insulation element 212, which is why it is preferably formed to be transparent for a wavelength range of the optical-fiberless signal 161 and/or 162 and is arranged in a course of a path of the optical-fiberless signals 161 and 162. However, such an implementation remains optional if a height of the insulation element 212, e.g. along the direction 140z, is so low that the path of the optical-fiberless signals 161 and/or 162 is not impaired or only insignificantly impaired. Alternatively or additionally, a recess or a hole could also be provided in the insulation element 212, which e.g. does not extend onto a base surface 42 of the holding structure 111, which is why leakage currents would run along the direction 140z in order to reach the respective other optical transceiver 120/121.

The insulation element 211 may be pressed into the holding structure in a contact region, e.g. in a region of the insulation element 211 covered by the circuit board 110, and comprise, in the contact region, depressions, referred to as lugs, with respect to the holding structure, configured to provide a clamping force with respect to the holding structure. In other words, e.g., the insulation element 212 may be pressed into the recess 211 of FIG. 3 or fastened in some other manner. Alternatively, the insulation element 212 could also be fastened or arranged on the surface 42, e.g. by a joining process.

It is pointed out that the insulation element 212 is not necessarily a separate element for electrical insulation with regard to the leakage current between the optical transceivers 120 and 121. In an advantageous implementation, which will be described in detail later, it is possible that the insulation element 212 at least partially encapsulates the optical device 120 and/or 121, which may enable additional improvement with regard to durability and dielectric strength.

Other provisions for a leakage current path extension are likewise the subject matter of embodiments described herein. Such a leakage current path extension may be configured in an optocoupler according to embodiments to extend a path length of the leakage current compared to a direct path between the optical devices 120/121 to increase the dielectric strength compared to the direct path.

In other words, the insulation voltage may be further increased compared to FIG. 3 by inserting a material with higher dielectric strength into the slot 212. This is illustrated in FIG. 4 by the block 212. For example, the inserted insulator may be a cost-effective plastic that may already comprise a significantly higher dielectric strength than air. For example, the insulator may be configured with small lugs, elevations or depressions at a lower end so that it may be simply pressed into the slot for mounting and then clamped.

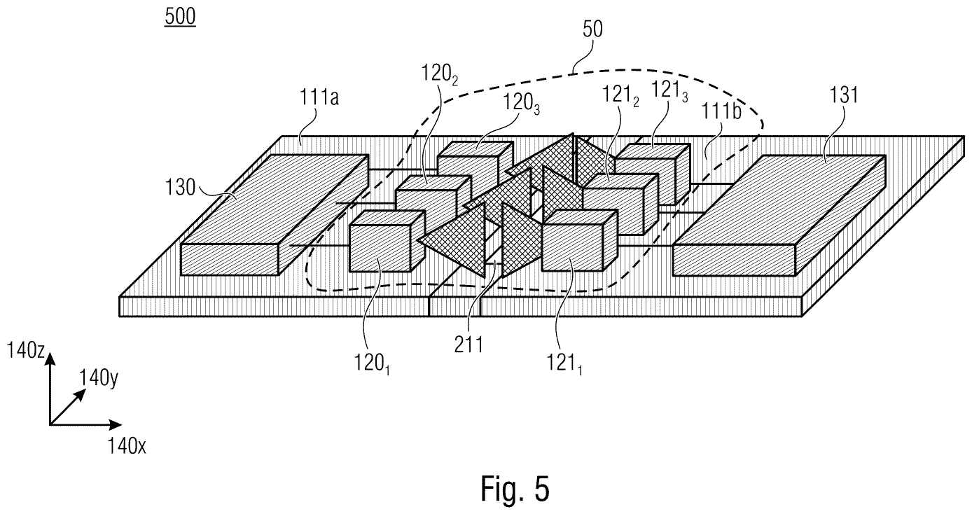

FIG. 5 shows a schematic block circuit diagram of a system 500 according to an embodiment in which an optocoupler 50 includes a plurality of transmitter pairs for optical-fiberless signals. Thus, for example, respective first optical devices 1201, 1202 and 1203 form together with a respective second optical device 1211, 1212 and 1213 a transmitter pair, i.e. the combination of the optical devices 1201, 1211; 1202, 1212; and 1203, 1213 forms one of a total of three illustrated transmitter pairs, wherein the number of 3 transmitter pairs is exemplary and may include an arbitrary value of at least 2, at least 3, at least 4 or more, e.g. at least 5, at least 7 or at least 10. Even if the system 500 is configured in the respective transmitter pair for a bidirectional communication, other embodiments may be implemented with a unidirectional communication at least in one of the transmitter pairs.

The transmitter pairs may enable temporally and/or spatially parallel operation of transmitted optical-fiberless signals, e.g. by being arranged next to one another on the holding structure and/or by implementing different wavelengths for the optical-fiberless signals. Different transmitter pairs may be used for different optical-fiberless channels and/or for different purposes and/or different transmission directions. Thus, on the basis of mutually different sensor elements, e.g., connected to the block 130 and/or 131, sensor data for mutually different sensor channels having mutually different transmitter pairs may be transmitted for different sensor elements. Alternatively or additionally, the different data channels may also be used to transmit other signals, e.g. control signals, and/or to transmit a control signal in at least one channel and a sensor signal in at least one other channel.

In other words, FIG. 5 shows an embodiment in which the bandwidth of the optocoupler is increased by placing a plurality of transceivers next to one another. In FIG. 5, this is indicated by the transceivers 1201, 1202, 1203 or 1211, 1212, 1213. Channel crosstalk may be avoided or sufficiently minimized by the transceivers transmitting or receiving very directionally, which may be implemented by respective channel optics. Alternatively or additionally, the distance between the devices of different transmitter pairs, e.g. along the direction 140y, may be selected to be sufficiently large, which does not rule out additional diversity in the wavelength range, according to which at least adjacent transmitter pairs use different and preferably disjoint wavelength ranges, at least with regard to the receiving optics.

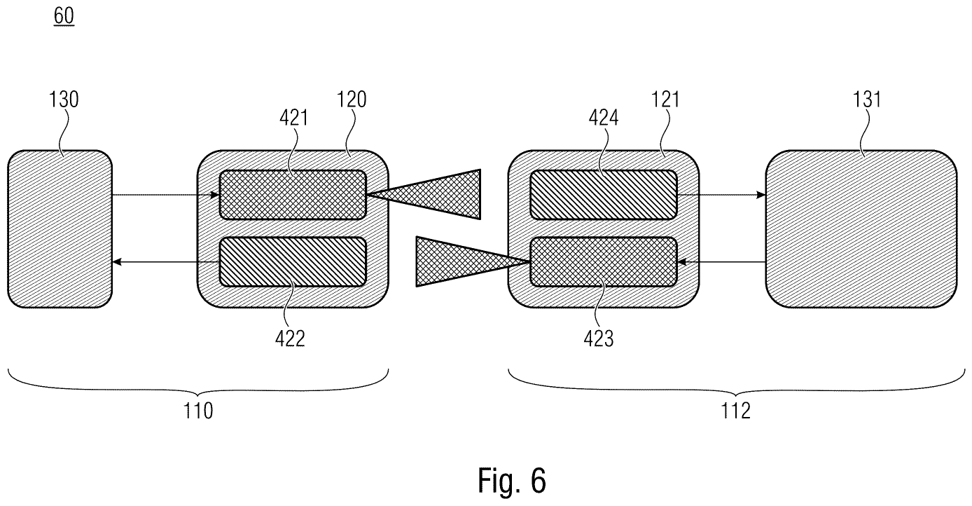

FIG. 6 shows a schematic block circuit diagram of an optocoupler 60 according to an embodiment, wherein the holding structure is not illustrated, the data source 130 and the data receiver 131 are therefore part of the optocoupler 60. In the embodiment of FIG. 6, data may be transmitted from the block 130 to the transceiver 120. A transmitter 421 of the transceiver 120 may be configured to transmit the data to an optical receiver 424 of the transceiver 121, e.g., which is arranged in a domain with high electrical potential.

The data is then forwarded to the block 131. The data may also be transmitted from the block 131 via the sender 423 of the transceiver 121 to the receiver 422 of the transceiver 120. From there, they may be forwarded to the block 130.

The transmitter 421 of the transceiver 120 may be arranged in any position relative to the receiver 424 of the transceiver 121. Likewise, the transmitter 423 of the transceiver 121 may be arranged in any position relative to the receiver 422 of the transceiver 120. This means that it is conceivable for the transmitter and receiver to be arranged next to one another, e.g. along the direction 140y, see e.g. FIG. 4. However, it is also conceivable for the transmitter and receiver to be arranged above one another, i.e. along the axis 140z. However, a radial arrangement is also conceivable, e.g. to the effect that the transmitter is arranged within a circular receiver aperture or vice versa, i.e. the optical transmitter encloses the optical receiver at the output aperture; or the optical receiver encloses the optical transmitter at the output aperture, e.g. as uninterrupted or interrupted rings, ellipses or polygons.

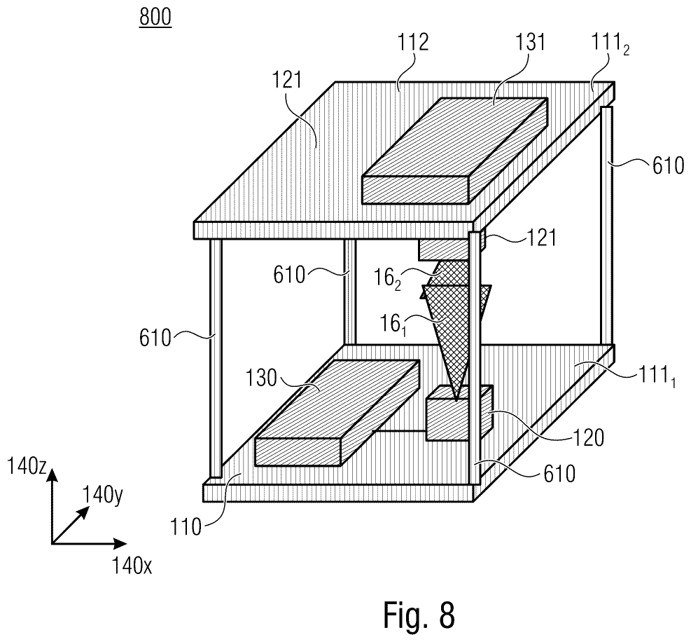

There may also be arrangement above one another, e.g. to the effect that the optocoupler is configured for operation in an optics arrangement, wherein the optics arrangement extends parallel to an optics plane, e.g. parallel to a 140x/140y plane, e.g. with reference to FIG. 8, such that the first optical device and the second optical device are arranged opposite one another and/or stacked in different planes. Deviating therefrom, an arrangement is illustrated with reference to FIGS. 2, 3 and 4, e.g., wherein the optics arrangement is arranged for example on the printed circuit board 111 and an optics plane is arranged for example at, on, or in the surface 42 and the optical devices are arranged at least substantially in a corresponding plane parallel to the optics plane. As a result, there is an offset between the two transmitters along only one direction, preferably the propagation direction of the optical-fiberless signal.

A further implementation of the radial arrangement may be implemented such that an optical transmitter of a transceiver and an optical receiver of the other optical device are positioned in a radial arrangement, such that the optical-fiberless signal is transmitted radially outward or radially inward.

With reference to FIG. 6, the block 131 and/or the block 130 may be configured as data source. For example, this block may comprise one or more sensors that may, e.g., generate large amounts of data with one or more analog-to-digital converters (ADCs). In the case of an ADC, this data may be transmitted serially via the optocoupler. If necessary, for this purpose, it may be converted beforehand into a serial bitstream with a high data rate with a multiplexer. It is also conceivable to transmit ADC data or data streams from individual or different sensors in parallel by placing a plurality of transceivers next to one another, see FIG. 5. Thus, sample rates with high resolution GS/s may also be transmitted.

The block 131 may be one or more chips and/or sensors. It is possible to use an FPGA/ASIC that comprises, e.g., an integrated ADC that may generate the data. It is also possible for the FPGA/ASIC to obtain or receive the data from a sensor via a data interface.

For example, the block 130 may receive sensor data from the high potential domain 112 via the optocoupler. The block 130 may further process these data. It is also conceivable to perform data processing in the block 131, but the available power in the high voltage domain or high potential domain 112 is generally limited, so that it may be advantageous to perform power-intensive calculations in the low potential domain 110. The block 130 may also provide a periphery that may provide one or more interfaces with which the data may be input into a network or distributed to other terminals. It is again pointed out that a direction in which data is transmitted is selected only by way of example, and in particular in light of the low-potential side and high-potential side, and the direction may be inverted without problems or extended into a bidirectional communication. Some embodiments provide that data is generated in the high potential domain by means of sensors and a data source is implemented, wherein the data is transmitted via the optocoupler. Furthermore, settings or configurations may be carried out on the circuits and/or sensors in the high potential domain via control signals that are transmitted in the direction of the sensors, so that a data sink is also implemented in the high potential domain.

In other words, FIG. 6 shows an electronic block circuit diagram of an optocoupler according to the invention.

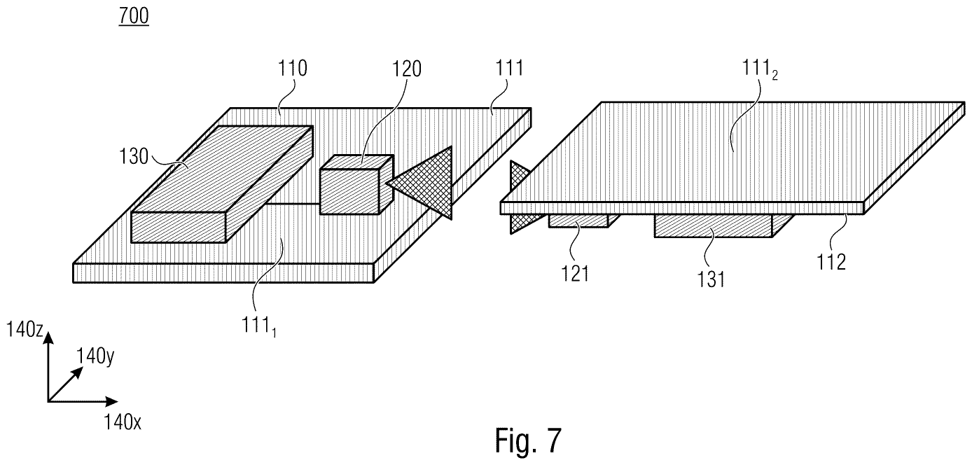

FIG. 7 shows a schematic perspective view of a system 700, wherein the circuit board structure 111 of the system 200 is modified such that, at least with regard to the optocoupler, the first optical device 120 is arranged on a first circuit board element 1111 and the second optical device 121 is arranged on a different second circuit board element 1112, wherein the circuit board elements 1111 and 1112 are spaced apart from one another. A relative alignment with respect to one another may ensure an extension of the holding structure, not illustrated. In an implementation independent thereof, optics mounting sides, i.e. sides of the circuit board elements 1111 and 1112 on which the optical devices are arranged, face one another, as illustrated in FIG. 7, or face away from one another. It is also not necessary for the optics mounting sides, as illustrated, to run parallel to one another.

In other words, FIG. 7 shows a further embodiment in which the two transceivers are placed on different circuit boards 1111 and 1112. In this embodiment, the circuit boards are rotated with respect to one another, this being optional.

If two separate circuit board elements are used, the field breakdown at the circuit board surfaces may become less likely compared to a one-piece implementation, even if this requires the placement of components across two circuit boards. Thus, the problem may be limited to a field breakdown at the housing surface of a device, which may likewise be easily overcome.

FIG. 8 shows a schematic block circuit diagram of a system 800 according to an embodiment, wherein the transceivers 120 and 121 of the optocoupler are arranged on two different circuit board elements 1111 and 1112, respectively, whose optics mounting sides are arranged facing one another, as described in connection with FIG. 7. The circuit board elements 1111 and 1112 may be arranged opposite one another, so that the emission of optical-fiberless signals may take place substantially perpendicular to a substrate surface.

As illustrated with reference to the block 131, a data source and/or a data receiver may be arranged on the same side, the optics mounting side, or an opposite side. It becomes clear that a surface requirement, e.g. with regard to chip area or on the printed circuit board, may be reduced with an arrangement according to FIG. 8. Maintaining the relative positioning may nevertheless be ensured by the holding structure comprising spacers 610 that position the circuit board elements 1111 and 1112 relative to one another at at least one location, preferably at or in regions where the optical communication is at most slightly influenced or uninfluenced.

In other words, FIG. 8 shows a further embodiment in which communication does not take place tangentially to the circuit board surface, but perpendicular to the circuit board surface, e.g. along the direction 140z, within the optocoupler. The two transceivers 120, 121 are seated on different circuit boards. Both circuit boards may, but need not, be fastened to one another. It is conceivable, e.g., to fix the circuit boards with the spacers 610. These spacers may be made of or include an insulator, e.g. ceramic or plastic, in order to achieve a high insulation voltage.

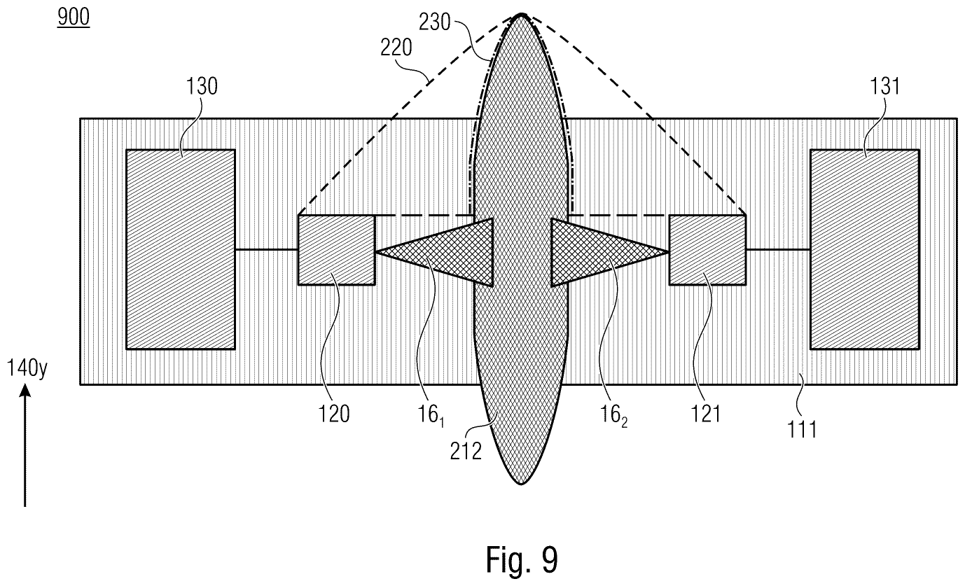

FIG. 9 shows a schematic top view of a system 900 according to an embodiment, which may represent a modification of the system 400. The insulation element 212 is here configured such that it protrudes beyond the circuit board 111 along positive and negative directions 140y, which further improves the insulation properties of the insulation element 212.

In other words, FIG. 9 shows a top view of the optocoupler, provided with an insulator, which increases a leakage gap 230 and an air gap 220 between electrical contacts of the transceivers 120, 121 and thus increases the dielectric strength. In this case, both transceivers are arranged on a circuit board 111 so that they may form a complete optocoupler unit. In this way, a particularly compact optocoupler may be achieved. For example, the insulator 212 may be made of an optically transparent plastic, at least with regard to the optical-fiberless signals 161 and 162. In other words, FIG. 9 shows an embodiment of the optocoupler with an optically transparent insulator formed specifically for increasing the insulation.

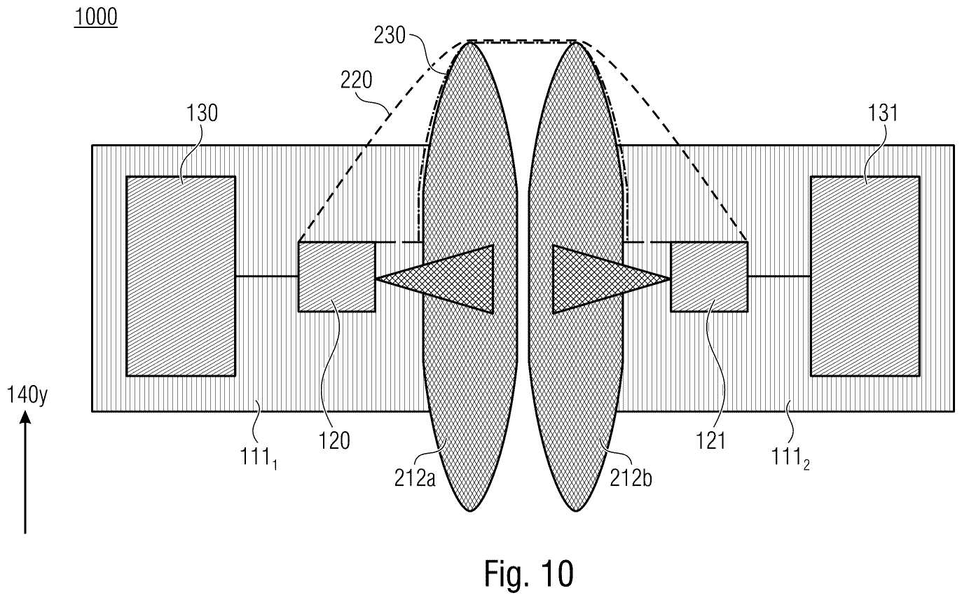

Starting from FIG. 9, FIG. 10 shows a schematic top view of a system 1000, wherein the circuit board structure 111 is divided into two circuit board elements 1111 and 1112, as described in connection with FIG. 7. Furthermore, an electrical insulation element 212a is arranged on the first circuit board element 1111 and faces the second circuit board element 1112. A further electrical insulation element 212b is arranged on the second circuit board element 1112 and faces the first circuit board element 1111. In other words, the insulation element 212 of the system 900 may be divided similarly to the circuit board structure 111, wherein the elements may also be configured without an insulation element, as illustrated in FIG. 7, or an insulation element may be arranged only on one of the two circuit board elements 1111 or 1112. However, an implementation according to FIG. 10 enables similar or even identical individual components of the overall system 1000 to be produced and arranged with respect to one another and fastened to one another by a holding structure.

In other words, FIG. 10 shows a configuration similar to FIG. 9. An implementation with two separate circuit boards 1111 and 1112 is shown, wherein the insulator 212a and 212b is also contained on each side of the optocoupler, enabling a modular design. In this way, the optocoupler may be realized with different distances between the optical devices, thus obtaining different dielectric strengths. It would be conceivable for the two sides of the optocoupler then formed to be able to be arranged with a smaller distance due to the increased dielectric strength on account of the insulator 212a and 212b than the distances, typically maintained on circuit boards, between the high-voltage region and the low-voltage region, which is typically 0.005 mm/V according to VDE 110. In other words, FIG. 10 shows an embodiment of a modular optocoupler having in each case one optically transparent insulator formed specifically for increasing the insulation per module.

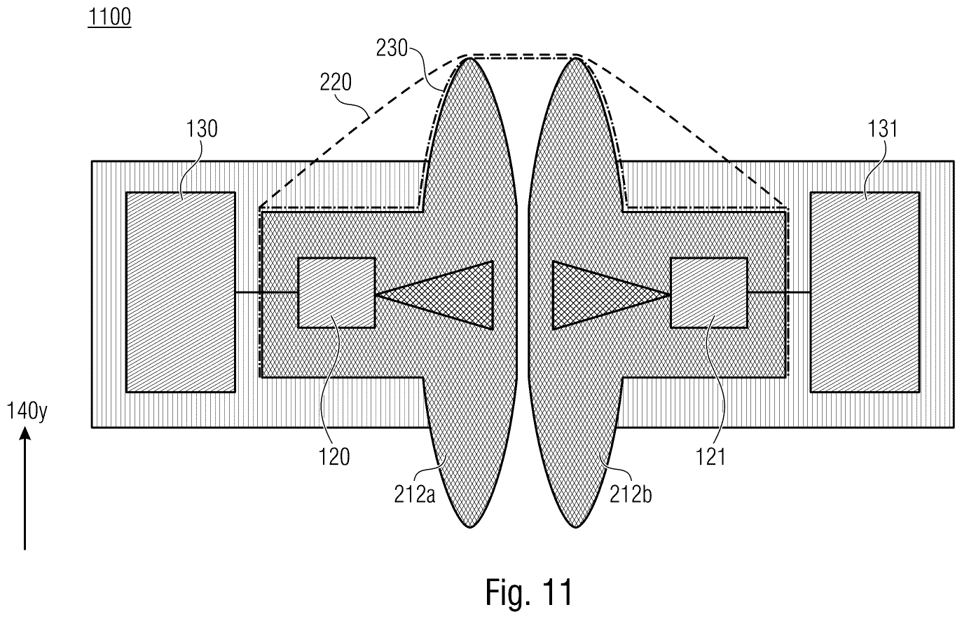

FIG. 11 shows a schematic top view of a system 1100 according to an embodiment, which further configures the embodiment of FIG. 10 in that the electrical insulation element 212a completely or partially encapsulates the first optical device 120 and/or the electrical insulation element 212b completely or partially encapsulates the second optical device 121. In this case, encapsulation may relate in particular to the electrical contacts, but is not restricted thereto. By means of the encapsulation, the electrical insulation capability may be further improved, but alternatively or additionally, protection from environmental influences may also be obtained, e.g., with regard to dirt particles and/or moisture. To this end, the insulation element 212a, 212b may be applied to the optical device 120, 121 as a type of cover, e.g. by plugging in or by gluing, but the optical device 120 or 121 may also be cast in the insulator, which may increase the tightness but may possibly prevent an exchangeability of the insulator.

In other words, FIG. 11 shows an embodiment of a modular optocoupler having in each case one optically transparent insulator formed specifically for increasing the insulation per module, wherein the insulator incorporates the transceiver modules in order to further increase the insulation.

Embodiments of the present invention further relate to the beam shaping (or beam forming) of the optical devices or transceivers described herein. Thus, in the context of embodiments described herein, each of the transceivers may be formed, e.g., in accordance with DE 10 2023 204 393 A1. Such a transceiver may be placed as a component on a circuit board in embodiments described herein and may transmit data tangentially to the circuit board surface. The lens of the transceiver may be configured such that the communication is possible bidirectionally, i.e. in both directions. The transmission channel and the reception channel lie spatially above one another, so that two opposite transceivers may also communicate with one another when they are rotated with respect to the optical axis. In the context of embodiments described herein, it is possible in this respect to place the two transceivers on two separate circuit boards and to rotate the two circuit boards about the optical axis of the transceivers and the communication nevertheless functions, see in this respect e.g. FIG. 7. Alternatively or additionally, a shape or implementation of at least one of the optical devices described herein may be in accordance with US Patent 2021/143912 A1, e.g. in order to implement an emission orthogonal to the circuit board surface, as used, e.g., in the system 800.

Starting from these references, the first optical device may be configured to emit the optical-fiberless signal substantially in parallel to a mounting surface on which the first optical device is arranged, e.g. the optics plane, or wherein the first optical device is configured to emit the optical-fiberless signal substantially perpendicular to the mounting surface, wherein the deflection of a beam direction, e.g. using mirrors or the like, is readily possible.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device.

Depending on specific implementation requirements, embodiments of the invention may be implemented in hardware or in software. Implementation may be effected while using a digital storage medium, for example a floppy disc, a DVD, a Blu-ray disc, a CD, a ROM, a PROM, an EPROM, an EEPROM or a FLASH memory, a hard disc or any other magnetic or optical memory which has electronically readable control signals stored thereon which may cooperate, or cooperate, with a programmable computer system such that the respective method is performed. This is why the digital storage medium may be computer-readable. Some embodiments in accordance with the invention thus comprise a data carrier which comprises electronically readable control signals that are capable of cooperating with a programmable computer system such that any of the methods described herein is performed.

Generally, embodiments of the present invention may be implemented as a computer program product having a program code, the program code being effective to perform any of the methods when the computer program product runs on a computer. The program code may also be stored on a machine-readable carrier, for example.

Other embodiments include the computer program for performing any of the methods described herein, said computer program being stored on a machine-readable carrier.

In other words, an embodiment of the inventive method thus is a computer program which has a program code for performing any of the methods described herein, when the computer program runs on a computer. The data carrier, the digital storage medium, or the recorded medium are typically tangible, or non-volatile. A further embodiment of the inventive methods thus is a data carrier (or a digital storage medium or a computer-readable medium) on which the computer program for performing any of the methods described herein is recorded.

A further embodiment of the inventive method thus is a data stream or a sequence of signals representing the computer program for performing any of the methods described herein. The data stream or the sequence of signals may be configured, for example, to be transferred via a data communication link, for example via the internet.

A further embodiment includes a processing unit (or processing means), e.g. a computer or a programmable logic device, configured or adapted to perform any of the methods described herein.

A further embodiment includes a computer on which the computer program for performing any of the methods described herein is installed.

In some embodiments, a programmable logic device (for example a field-programmable gate array, an FPGA) may be used for performing some or all of the functionalities of the methods described herein. In some embodiments, a field-programmable gate array may cooperate with a microprocessor to perform any of the methods described herein. Generally, the methods are performed, in some embodiments, by any hardware device.

Said hardware device may be any universally applicable hardware such as a computer processor (CPU), or may be a hardware specific to the method, such as an ASIC.

The above-described embodiments merely represent an illustration of the principles of the present invention. It is understood that other persons skilled in the art will appreciate modifications and variations of the arrangements and details described herein. This is why it is intended that the invention be limited only by the scope of the following claims rather than by the specific details that have been presented herein by means of the description and the discussion of the embodiments.

1. Optocoupler comprising:
a first optical device having beamforming optics configured to emit an optical-fiberless signal using the beamforming optics;
a second optical device galvanically isolated from the first optical device and configured to receive the optical-fiberless signal and convert it into an electrical signal;
a holding structure configured to position the first optical device and the second optical device in a fixed relative position with respect to one another for the transmission and reception of the optical-fiberless signal.

2. Optocoupler according to claim 1, wherein an optical transmission path between the first optical device and the second optical device comprises a length of at least 5 mm.

3. Optocoupler according to claim 1, wherein the optical-fiberless signal is a first optical-fiberless signal; wherein the second optical device is configured to transmit a second optical-fiberless signal to the first optical device.

4. Optocoupler according to claim 1, comprising an electrical insulation region between the first optical device and the second optical device.

5. Optocoupler according to claim 1, wherein the holding structure comprises a circuit board structure, and the first optical device and the second optical device are arranged on the circuit board structure.

6. Optocoupler according to claim 5, wherein the first optical device is arranged on an optics mounting side of a first circuit board element of the circuit board structure, and the second optical device is arranged on an optics mounting side of a spaced apart second circuit board element, wherein the optics mounting sides face one another or face away from one another.

7. Optocoupler according to claim 5, comprising a first electrical insulation element that is arranged on the first circuit board element and faces the second circuit board element; and a second electrical insulation element that is arranged on the second circuit board element and faces the first circuit board element.

8. Optocoupler according to claim 7, wherein the first electrical insulation element at least partially encapsulates the first optical device; and/or wherein the second electrical insulation element at least partially encapsulates the second optical device.

9. Optocoupler according to claim 5, wherein the circuit board structure comprises, along a distance between the first optical device and the second optical device, a recess comprising an expansion perpendicular to the distance in order to provide a leakage current path extension.

10. Optocoupler according to claim 5, wherein the holding structure comprises an electrically insulating insulation element that is at least partially arranged along a distance between the first optical device and the second optical device.

11. Optocoupler according to claim 10, wherein the insulation element is pressed into a recess of the holding structure in a contact region and comprises, in the contact region, with respect to the holding structure, elevations or depressions configured to provide a clamping force with respect to the holding structure.

12. Optocoupler according to claim 10, wherein the insulation element at least partially encapsulates the first optical device and/or the second optical device.

13. Optocoupler according to claim 1, comprising a leakage current path extension configured to extend a path length of a leakage current compared to a direct path and between the first optical device and the second optical device.

14. Optocoupler according to claim 1, wherein the first optical device and the second optical device form a first transmitter pair, and a plurality of transmitter pairs configured for temporally and/or spatially parallel operation is arranged on the holding structure.

15. Optocoupler according to claim 14, configured to transmit, on the basis of mutually different sensor elements, sensor data for mutually different sensor channels with mutually different transmitter pairs.

16. Optocoupler according to claim 1, wherein the optocoupler is configured for operation in an optics arrangement, wherein the optics arrangement extends parallel to an optics plane, wherein the first optical device and the second optical device are arranged in a corresponding plane parallel to the optics plane; or
wherein the optocoupler is configured for operation in an optics arrangement, wherein the optics arrangement extends parallel to an optics plane, wherein the first optical device and the second optical device are arranged opposite one another in different planes; or
wherein an optical transmitter of the first optical device and an optical receiver of the second optical device are positioned in a radial arrangement, and the optical transmitter encloses the optical receiver at the output aperture; or the optical receiver encloses the optical transmitter at the output aperture.

17. Optocoupler according to claim 1, formed as an integrated device or part of an integrated system.

18. Optocoupler according to claim 1, wherein the first optical device is configured to emit the optical-fiberless signal substantially in parallel to a mounting surface on which the first optical device is arranged; or wherein the first optical device is configured to emit the optical-fiberless signal substantially perpendicular to the mounting surface.

19. System comprising:
an optocoupler according to claim 1; and
a data source coupled to the first optical device in order to transmit data to the second optical device by means of the optical-fiberless signal; and
a data receiver configured to receive the data from the second optical device.

20. System according to claim 19, wherein the data source is electrically coupled to a high-potential side of the system and the data receiver is electrically coupled to a low-potential side of the system.
